(19) United States
(12) Patent Application Publication
(10) Pub. No.: US 2026/0171378 A1
(43) Pub. Date: Jun. 18, 2026

(54) UNIFORM OXIDE LAYERS

(71) Applicant: Taiwan Semiconductor Manufacturing Company, Ltd., Hsinchu (TW)

(72) Inventors: Chia-Hsi Wang, Xihu Township (TW); Yen-Yu Chen, Taichung City (TW); Jen-Hao Chien, Taipei City (TW)

(73) Assignee: Taiwan Semiconductor Manufacturing Company, Ltd., Hsinchu (TW)

(21) Appl. No.: 18/980,307

(22) Filed: Dec. 13, 2024

(51) Int. Cl. H01J 37/32; C23C 14/34; C23C 14/50; C23C 14/54; H10N 50/01; H10N 50/85

(52) U.S. Cl. CPC H01J 37/3299; C23C 14/34; C23C 14/50; C23C 14/542; H01J 37/32697; H10N 50/01; H10N 50/85; H01J 2237/24564; H01J 2237/332

(57) ABSTRACT

Provided are metal oxide layers and methods and systems for forming metal oxide layers. A method includes receiving a workpiece in an apparatus for deposition, wherein the apparatus for deposition comprises a chamber and electrostatic pads disposed in the chamber to accommodate the workpiece; flowing oxygen into the chamber through a shutter tube; monitoring an electrostatic accumulation over the workpiece; and adjusting the electrostatic accumulation, wherein adjusting the electrostatic accumulation comprises adjusting heights of the electrostatic pads to form a deposited layer with a selected thickness uniformity.

### BACKGROUND

Semiconductor device fabrication is a process for forming integrated chips (ICs). The fabrication process is a multiple-step sequence that comprises performing various deposition, photolithographic, and chemical processing steps to gradually form integrated circuits on a semiconductor wafer. Many integrated circuits are formed on the semiconductor wafer at the same time, and then the semiconductor wafer undergoes a dicing process to form the ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1B illustrate various cross-sectional views of some embodiments of a process tool comprising an adjustable wafer chuck.

FIGS. 2A-2B illustrates various views of some other embodiments of the adjustable wafer chuck.

FIG. 3 illustrates a cross-sectional view of some other embodiments of the adjustable wafer chuck.

FIG. 4 illustrates a cross-sectional view of some other embodiments of the adjustable wafer chuck.

FIG. 5 illustrates a cross-sectional view of some other embodiments of the adjustable wafer chuck.

FIG. 6 illustrates a cross-sectional view of some other embodiments of the adjustable wafer chuck.

FIGS. 7A-7B illustrate diagrams of some embodiments of a system configured to operate some embodiments of the adjustable wafer chuck.

FIG. 8 illustrates a top view of some other embodiments of the adjustable wafer chuck.

FIG. 9 illustrates a top view of some other embodiments of the adjustable wafer chuck.

FIG. 10 illustrates a top view of some other embodiments of the adjustable wafer chuck.

FIG. 11 illustrates a top view of some other embodiments of the adjustable wafer chuck.

FIG. 12 illustrates a cross-sectional view of some embodiments of the adjustable wafer chuck.

FIG. 13 is a bottom schematic view of the shutter tube of the system of FIG. 1, according to certain embodiments herein.

FIG. 14 illustrates top and cross-sectional schematic views of an adjustable chuck according to certain embodiments herein.

FIG. 15 is a schematic view of a portion of semiconductor device formed according to certain embodiments herein.

FIG. 16 is a schematic view of a portion of the semiconductor device of FIG. 15, according to certain embodiments herein.

FIG. 17 is a schematic of a magnetic-tunnel junction (MTJ) film stack, according to certain embodiments herein.

FIG. 18 illustrates a flowchart illustrating a method for forming a uniform metal oxide layer according to embodiments herein.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. As used herein, “directly over” refers to a vertical alignment of features such that, when an overlying feature that is directly over an underlying feature, a vertical axis passes through both features. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “directly over”, “over”, “overlying”, “above”, “upper”, “top”, “under”, “underlying”, “beneath”, “below”, “lower”, “bottom”, “side”, “positive slope” and “negative slope” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

All numbers in this description indicating amounts, ratios of materials, physical properties of materials, and/or use are to be understood as modified by the word “about,” except as otherwise explicitly indicated. When modifying a numerical value in the specification or claims, “about” denotes an interval of accuracy, familiar and acceptable to a person skilled in the art. In general, such interval of accuracy is ±ten percent. Thus, “about ten” means nine to eleven.

In certain embodiments herein, a “material layer” is a layer that includes at least 50 wt. % of the identified material, for example at least 60 wt. % of the identified material, at least 75 wt. % of the identified material, at least 90 wt. % of the identified material, or at least 99 wt. % of the identified material; and a layer that is a “material” includes at least 50 wt. % of the identified material, for example at least 60 wt. % of the identified material, at least 75 wt. % of the identified material, at least 90 wt. % of the identified material, or at least 99 wt. % of the identified material. For example, certain embodiments, each of a titanium nitride layer and a layer that is titanium nitride is a layer that is at least 50 wt. %, at least 60 wt. %, at least 75 wt. %, titanium nitride, at least 90 wt. % titanium nitride, or at least 99 wt. % titanium nitride.

For the sake of brevity, well-known techniques related to semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

An integrated chip (IC) comprises multiple layers (e.g., dielectric layers, conductive layers, etc.) disposed over a substrate. The multiple layers are formed by a semiconductor device fabrication process. The fabrication process comprises performing various deposition, photolithography, and removal processes to form integrated circuits on a semiconductor wafer. Typically, many integrated circuits are formed on the semiconductor wafer at the same time, and then the semiconductor wafer undergoes a dicing process to dice the semiconductor wafer into chips, thereby forming a plurality of ICs.

During the fabrication process, wafer chucks are generally relied upon to securely hold the semiconductor wafer during fabrication. For example, some deposition processes (e.g., physical vapor deposition (PVD), chemical vapor deposition (CVD), etc.) rely upon a wafer chuck having a plurality of contact pads to securely hold the semiconductor wafer in place while a layer is formed on/over the semiconductor wafer. The plurality of contact pads may improve the chucking performance (e.g., a more uniform grip force across the wafer, improved cooling across the wafer, etc.). However, the plurality of contacts pads are prone to premature wear, which may decrease chucking performance (e.g., non-uniform grip force across the wafer, increased back side pressure faults, etc.).

One potential cause of the premature wear of the plurality of contacts pads is due to warpage of the semiconductor wafer (e.g., loading a warped semiconductor wafer on the wafer chuck, a deposition process causing a semiconductor wafer to warp while the wafer is being clamped by the wafer chuck, etc.). More specifically, a warped semiconductor wafer may cause premature wear of the plurality of contacts pads due to the warped semiconductor wafer, when clamped in the wafer chuck, causing non-uniform distances between the warped semiconductor wafer and the contact pads (e.g., the warped/bowed shape (e.g., concave, convex, etc.) of the semiconductor wafer causes some contact pads to be closer to the wafer than other contact pads). This variable distance between the plurality of contact pads and the semiconductor wafer may result in increased forces on some of the plurality of contact pads, which may lead to premature wear of the some of the plurality of contact pads. Premature wear of the contact pads increases a cost to fabricate ICs due to, for example, decreased productivity (e.g., due to tool down time), increased maintenance costs (e.g., cost to repair the contact pads, cost to replace the wafer chuck, etc.), and so forth.

Various embodiments of the present application are directed toward an adjustable wafer chuck. The adjustable wafer chuck is configured to hold (e.g., clamp) a wafer. The adjustable wafer chuck comprises a base portion and a pad portion. The base portion comprises a plurality of adjustable base structures. The pad portion is disposed on a first side of the base portion. The pad portion comprises a plurality of contact pads (e.g., minimum contact area (MCA) pads) affixed to the plurality of adjustable base structures. Each of the adjustable base structures are configured to move along a plane in a first direction and configured to move along the plane in a second direction that is opposite the first direction.

Because the adjustable base structures are configured to move in the first and second directions along the plane, and because the plurality of contact pads are affixed to the plurality of adjustable base structures, distances between the plurality of contact pads and the wafer may be adjusted (e.g., tuned in relation to a feedback signal). As such, when the adjustable wafer chuck is holding a warped wafer, the distances between the plurality of contact pads and the wafer may be more uniform across the warped wafer than in comparison to a typical wafer chuck (e.g., a non-adjustable wafer chuck). Thus, the plurality of contact pads of the adjustable wafer chuck may be less prone to premature wear. Accordingly, the adjustable wafer chuck may decrease a cost to fabricate ICs (e.g., improve productivity, decrease maintenance costs, etc.).

In certain embodiments of the present application, an adjustable wafer chuck is controlled and operated to form a uniform oxide layer over a workpiece, such as a wafer. For example, conditions around the wafer and/or properties of the oxide being deposited are monitored and, in response to the monitored conditions and/or properties, the adjustable chuck is adjusted. For example, regions of the chuck may be raised or lowered to adjust flow characteristics, and/or oxygen concentration in the local environment around the wafer or around regions of the wafer. As a result, the oxide concentration of the deposited material may be adjusted and/or the thickness of the layer being formed may be controlled.

In certain embodiments, the introduction and flow of oxygen into and within the deposition chamber is controlled to form a uniform oxide layer over a workpiece, such as a wafer. For example, oxygen may be fed into the chamber by an adjustable shutter tube. The location of shutter tube may be adjusted. For example, the shutter tube may be moved laterally (parallel to the wafer) or vertically (toward or away from the wafer). Also, the flow rate of oxygen through the shutter tube may be adjusted, i.e., increased or decreased.

In certain embodiments, the adjustable chuck and adjustable shutter tube are dynamically operated i.e., adjusted during the deposition process.

Systems and methods for depositing oxide layers provide for control to form oxide layers having improved thickness uniformity. The oxide layers formed according to methods herein may be used in fabrication processes for forming FinFET device, gate-all-around (GAA) devices, advanced devices, industry semi-completed products or other devices or products. Further, methods herein may be used in front-end-of-line (FEOL) or back-end-of-line (BEOL) processing.

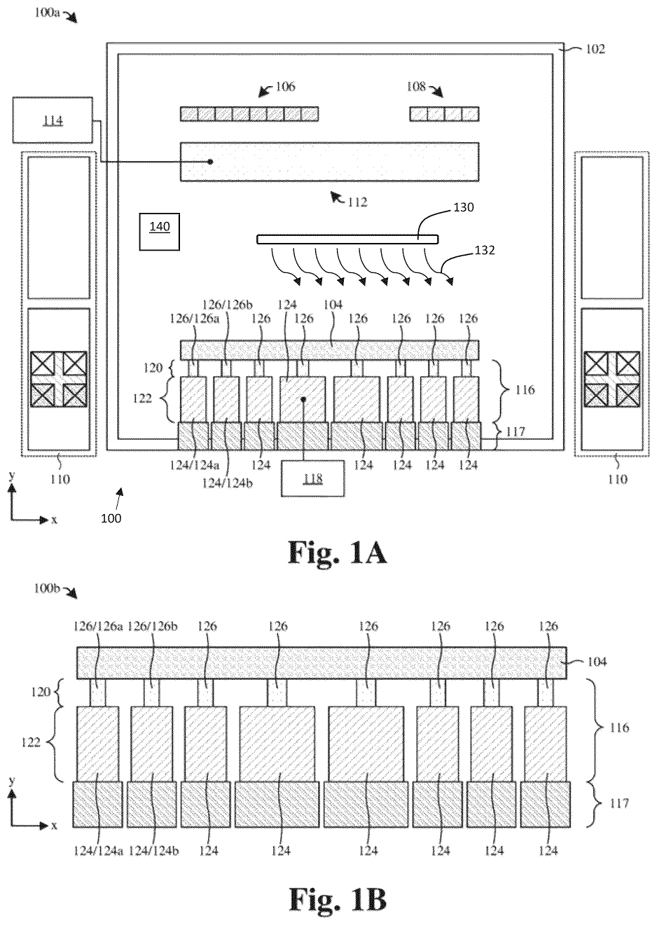

FIGS. 1A-1B illustrate various cross-sectional views 100 a-100 b of some embodiments of a process tool comprising an adjustable wafer chuck 116. More specifically, FIG. 1A illustrates a cross-sectional view 100 a of the process tool 100 comprising the adjustable wafer chuck 116, and FIG. 1B illustrates an enlarged cross-sectional view 100 b of some embodiments of the adjustable wafer chuck 116 illustrated in FIG. 1A.

As shown in the various cross-sectional views 100 a-100 b of FIGS. 1A-1B, the process tool (e.g., fabrication tool) comprises a chamber housing 102 defining a processing chamber. In some embodiments, the chamber housing 102 may be or comprise, for example, steel (e.g., stainless steel), aluminum, or the like. In some embodiments, the process tool is configured for use in a deposition process (e.g., physical vapor deposition (PVD), chemical vapor deposition (CVD), etc.), an etching process, a wafer testing process (e.g., wafer probing), or the like.

For example, in some embodiments, the process tool may be configured as a deposition process tool (e.g., DC sputtering process tool, RF sputtering process tool, etc.) that is configured to deposit a layer on/over a wafer 104 (e.g., a semiconductor wafer). In such embodiments, the process tool may comprise a first magnet 106, a second magnet 108 (e.g., LDR magnet), a third magnet 110 (e.g., electromagnet), and a sputtering target 112 (e.g., a sputtering target). Further, the process tool may comprise a first power source 114 (e.g., DC power source, AC power source, RF power source, etc.). In some embodiments, the first power source 114 is electrically coupled to the sputtering target 112. In further embodiments, the sputtering target 112 may be or comprise, for example, magnesium (Mg), aluminum (Al), strontium (Sr), iron (Fe), nickel (Ni), cobalt (Co), manganese (Mn), titanium (Ti), copper (Cu), tantalum (Ta), some other material suitable for sputtering, or a combination of the foregoing.

In some embodiments, the process tool may be utilized to deposit the layer on the wafer 104 by flowing a processing gas (e.g., argon (Ar)) into the chamber housing 102. The first power source 114 provides power (e.g., a DC voltage signal) to the sputtering target 112. An electrical charge (e.g., positive charge) is applied to the wafer 104. During processing, the environment inside the chamber housing 102 is such that a plasma is generated inside the chamber housing 102 that results in atoms of the sputtering target 112 being ejected off into the plasma (e.g., via bombardment of the sputtering target 112) and being deposited on the wafer 104. In some embodiments, the first magnet 106, the second magnet 108, and/or the third magnet 110 are utilized during the deposition process to improve the deposition characteristics of the layer.

Also shown in the various cross-sectional views 100 a-100 b of FIGS. 1A-1B, an adjustable wafer chuck 116 is disposed in the chamber housing 102. The adjustable wafer chuck 116 is configured to hold (e.g., clamp) the wafer 104 while a fabrication process is performed in the processing chamber. For example, the adjustable wafer chuck 116 is configured to hold the wafer 104 inside the processing chamber during the deposition process (e.g., the process of depositing the layer on the wafer 104). In some embodiments, the adjustable wafer chuck 116 may be disposed on a chuck pedestal 117 that is configured to support the adjustable wafer chuck 116. In some embodiments, the chuck pedestal 117 comprises an insulating material that electrically insulates the adjustable wafer chuck 116 from the chamber housing 102.

In some embodiments, the adjustable wafer chuck 116 is an adjustable electrostatic chuck (ESC) (which may also be referred to as an adjustable electrostatic wafer chuck). In such embodiments, the adjustable wafer chuck 116 is configured to hold the wafer 104 via an electrostatic force. In further such embodiments, the adjustable wafer chuck 116 is electrically coupled to ESC circuitry 118. The ESC circuitry 118 is configured to turn the adjustable wafer chuck “ON” (e.g., via applying voltages to chucking electrodes) to electrostatically clamp the wafer 104 to the adjustable wafer chuck 116. In some embodiments, the adjustable wafer chuck 116 is configured to withstand operation in a high temperature process tool (e.g., the adjustable wafer chuck 116 may be a high temperature electrostatic chuck that can operate in temperatures between about 200° C. and about 450° C.). In some embodiments, the adjustable wafer chuck 116 is configured to withstand operation in a low temperature process tool (e.g., the adjustable wafer chuck 116 may be a super low temperature electrostatic chuck that can operate in temperatures as low as at least negative 40° C.).

The adjustable wafer chuck 116 comprises a pad portion 120 and a base portion 122. The base portion 122 comprises a plurality of adjustable base structures 124. The pad portion 120 is disposed on a side (e.g., an upper side) of the base portion 122. The pad portion 120 comprises a plurality of contact pads 126 (e.g., a plurality of minimum contact area (MCA) pads). In some embodiments, the plurality of adjustable base structures 124 are or comprise, for example, a metal (e.g., aluminum, steel, etc.), a polymer, a plastic, a ceramic, or the like. In some embodiments, the plurality of contact pads 126 are or comprise, for example, a ceramic (e.g., titanium nitride (TiN)), a polymer, a plastic, some other suitable material of a combination of the foregoing. In some embodiments, the plurality of contact pads 126 are or comprise a different material than the plurality of adjustable base structures 124.

The plurality of contact pads 126 are affixed to the plurality of adjustable base structures 124. In some embodiments, each of the contact pads of the plurality of contact pads 126 corresponds to one of the adjustable base structures. For example, a first contact pad 126 a of the plurality of contact pads 126 corresponds to a first adjustable base structure 124 a of the plurality of adjustable base structures 124, a second contact pad 126 b of the plurality of contact pads 126 corresponds to a second adjustable base structure 124 b of the plurality of adjustable base structures 124, and so forth. Each contact pad is affixed to its corresponding one of the plurality of adjustable base structures 124. For example, the first contact pad 126 a is affixed to the first adjustable base structure 124 a, the second contact pad 126 b is affixed to the second adjustable base structure 124 b, and so forth.

The plurality of contact pads 126 may be affixed to the plurality of adjustable base structures 124 by various means. For example, the plurality of contact pads 126 may be affixed to the plurality of adjustable base structures 124 via an adhesive. In other embodiments, the plurality of contact pads 126 may be affixed to the plurality of adjustable base structures 124 via one or more bonds (e.g., bonded to the plurality of adjustable base structures 124, for example, via chemical bonds between the material of the plurality of contact pads 126 and the material of the plurality of adjustable base structures 124). In yet other embodiments, the plurality of contact pads 126 may be directly affixed to a plurality of intermediate plates (e.g., polymer plates, ceramic plates, etc.) that are affixed to the plurality of adjustable base structures 124 (e.g., via an adhesive, a mechanical faster (e.g., bolt), or the like). It will be appreciated that other means of affixing the plurality of contact pads 126 to the plurality of adjustable base structures 124 are amenable.

The plurality of adjustable base structures 124 are configured to move along a plane (the y-plane) in a first direction (e.g., up) and a second direction (e.g., down) opposite the first direction. The plurality of adjustable base structures 124 are configured to move along the plane so that each of the plurality of contact pads 126 are spaced about a same distance from the wafer during a fabrication step (e.g., during a deposition process). In further embodiments, the plurality of adjustable base structures 124 may be configured to move along the plane so that each of the plurality of contact pads 126 contact the wafer during the fabrication step. In some embodiments, the plurality of adjustable base structures 124 are configured to move independently along the plane (y-plane). For example, the first adjustable base structure 124 a may move along the plane (y-plane) in the first direction and the second direction independent of any of the other plurality of adjustable base structures 124, the second adjustable base structure 124 b may move along the plane (y-plane) in the first direction and the second direction independent of any of the other plurality of adjustable base structures 124, and so forth.

Because the plurality of adjustable base structures 124 are configured to move in the first and second directions along the plane (y-plane), and because the plurality of contact pads 126 are affixed to the plurality of adjustable base structures 124, distances (chucking distances) between the plurality of contact pads 126 and the wafer 104 may be adjusted (e.g., tuned in relation to a feedback loop). As such, if the adjustable wafer chuck 116 is holding a warped wafer (e.g., a wafer having a concave or convex shape when viewed in the cross-sectional views illustrated in FIG. 1B), the distances between the plurality of contact pads 126 and the wafer 104 may be more uniform across the warped wafer than in comparison to a typical wafer chuck (e.g., a non-adjustable wafer chuck). Thus, the plurality of contact pads 126 of the adjustable wafer chuck may be less prone to premature wear. Accordingly, the adjustable wafer chuck 116 may decrease a cost to fabricate ICs (e.g., improve productivity, decrease maintenance costs, etc.).

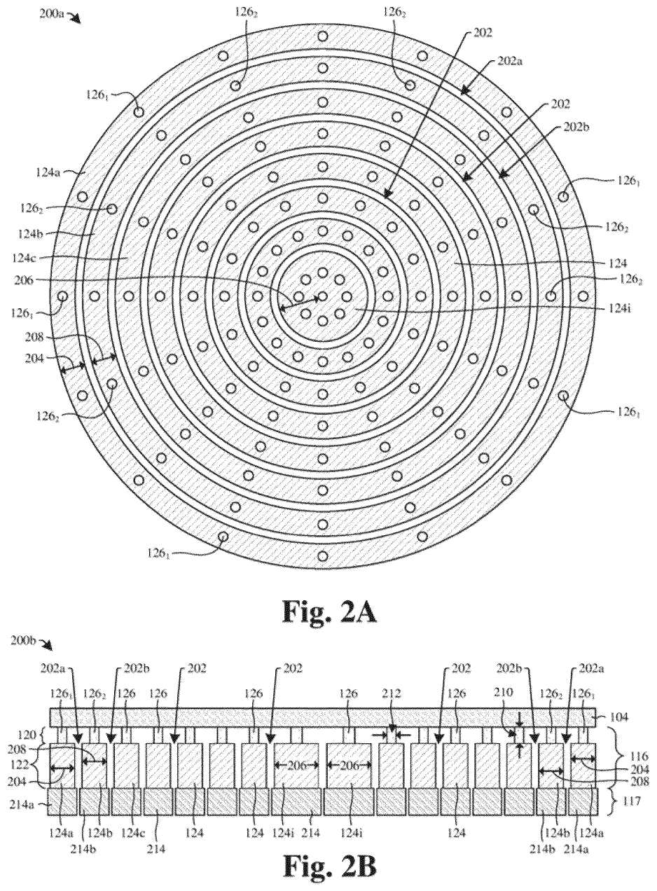

FIGS. 2A-2B illustrates various views 200 a-200 b of some other embodiments of the adjustable wafer chuck 116. More specifically, FIG. 2A illustrates a top view 200 a of some embodiments of the adjustable wafer chuck 116, and FIG. 2B illustrates a cross-sectional view 200 b of some embodiments of the adjustable wafer chuck 116 of FIG. 2A.

As shown in the various views 200 a-200 b of FIGS. 2A-2B, the plurality of adjustable base structures 124 may have ring-like shapes. The plurality of adjustable base structures 124 may be laterally spaced from one another. In some embodiments, the plurality of adjustable base structures 124 are laterally spaced from one another via gaps 202. For example, the first adjustable base structure 124 a is laterally spaced from the second adjustable base structure 124 b via a first gap 202 a, the second adjustable base structure 124 b is laterally spaced from a third adjustable base structure 124 c via a second gap 202 b, and so forth. The gaps 202 extend (completely) through the plurality of adjustable base structures 124, such that the plurality of adjustable base structures 124 are (completely) laterally spaced from one another. For example, an innermost sidewall of the first adjustable base structure 124 a laterally surrounds an outermost sidewall of the second adjustable base structure 124 b, and the innermost sidewall of the first adjustable base structure 124 a is laterally spaced from the outermost sidewall of the second adjustable base structure 124 b via the first gap 202 a. In some embodiments, the plurality of adjustable base structures 124 are concentric.

In some embodiments, an innermost adjustable base structure 124 i of the plurality of adjustable base structures 124 has a different thickness (e.g., ring thickness) than one or more of the other plurality of adjustable base structures 124. In further embodiments, the thickness (e.g., ring thickness) of the innermost adjustable base structure 124 i may be greater than a thickness of one or more of the other plurality of adjustable base structures 124. For example, the first adjustable base structure 124 a has a first thickness 204 (e.g., a first ring thickness), and the innermost adjustable base structure 124 i has a second thickness 206 (e.g., a second ring thickness) that is greater than the first thickness 204. In yet further embodiments, the innermost adjustable base structure 124 i may have a greater thickness (e.g., a greater ring thickness) than each of the other plurality of adjustable base structures 124. For example, the third adjustable base structure 124 c has a third thickness 208 (e.g., a third ring thickness); and the second thickness 206 is greater than the first thickness 204, the third thickness 208, and so forth.

In some embodiments, the first thickness 204 is substantially the same as the third thickness 208, and the second thickness 206 is greater than both the first thickness 204 and the third thickness 208. In other embodiments, the thicknesses of the plurality of adjustable base structures 124 may be substantially the same. For example, in some embodiments, the first thickness 204, the second thickness 206, and the third thickness 208 are substantially the same. In further embodiments, the thicknesses of the plurality of adjustable base structures 124 may be between about 1 millimeter (mm) and about 150 mm. In further embodiments, the thicknesses of the plurality of adjustable base structures 124 may be between about 25 mm and about 35 mm. For example, the first thickness 204 may be between about 25 mm and about 35 mm, the second thickness 206 may be between about 25 mm and about 35 mm, the third thickness 208 may be between about 25 mm and about 35 mm, and so forth. In yet further embodiments, the thicknesses of the plurality of adjustable base structures 124 may be about 30 mm.

Also shown in the various views 200 a-200 b of FIGS. 2A-2B, the plurality of contact pads 126 comprises a plurality of groups of contact pads 126 ₁-126 ₂. Each of the plurality of groups of contact pads 126 ₁-126 ₂ comprises one or more individual contact pads of the plurality of contact pads 126. For example, the groups of contact pads 126 ₁-126 ₂ comprises a first group of contact pads 126 ₁ and a second group of contact pads 126 ₂. The first group of contact pads 126 ₁ comprises one or more first contact pads of the plurality of contact pads 126. The second group of contact pads 126 ₂ comprises one or more second contact pads of the plurality of contact pads 126. The groups of contact pads 126 ₁-126 ₂ are respectively affixed to the plurality of adjustable base structures 124. For example, the contact pads of the first group of contact pads 126 ₁ are affixed to the first adjustable base structure 124 a, the contact pads of the second group of contact pads 126 ₂ are affixed to the second adjustable base structure 124 b, and so forth.

Each of the plurality of contact pads 126 have a height 210 and a width 212. In some embodiments, the height 210 is between about 0.5 mm and about 5 mm. In further embodiments, the height 210 is between about 1 mm and about 3 mm. In some embodiments, the heights of the contact pads of one of the plurality of groups of contact pads 126 ₁-126 ₂ are substantially the same. For example, the heights of the one or more first contact pads may be substantially the same (e.g., substantially the same includes small variations due to manufacturing processes). In further embodiments, the heights of the plurality of contact pads 126 may be substantially the same. In other embodiments, a height of one or more of the contact pads of a group of contact pads may be different that a height of one or more other contact pads of the group of contact pads. For example, the height of a first one of the first contact pads may be different than the height of a second one of the first contact pads. In yet other embodiments, a height of one of the plurality of contact pads 126 may differ from a height of one or more other of the plurality of contact pads 126. In yet further embodiments, the heights of the contact pads of one of the plurality of groups of contact pads 126 ₁-126 ₂ are substantially the same and the heights of the contact pads of another one of the plurality of groups of contact pads 126 ₁-126 ₂ are substantially the same, but the heights of the contact pads of the one of the plurality of groups of contact pads 126 ₁-126 ₂ are different than the heights of the contact pads of the another one of the plurality of groups of contact pads 126 ₁-126 ₂. For example, each of the first contact pads may have a first height and each of the second contact pads may have a second height different than the first height.

Also shown in the various views 200 a-200 b of FIGS. 2A-2B, the chuck pedestal 117 may comprise a plurality of pedestal structures 214. For example, the chuck pedestal 117 may comprise a first pedestal structure 214 a, a second pedestal structure 214 b, and so forth. In some embodiments, the plurality of adjustable base structures 124 are respectively disposed on (e.g., affixed to) the plurality of pedestal structures 214. For example, the first adjustable base structure 124 ₐ is disposed on the first pedestal structure 214 ₐ, the second adjustable base structure 124 _{b} is disposed on the second pedestal structure 214 _{b}.

The plurality of pedestal structures 214 respectively correspond to the plurality of adjustable base structures 124. For example, the first pedestal structure 214 a corresponds to the first adjustable base structure 124 a, the second pedestal structure 214 b corresponds to the second adjustable base structure 124 b, and so forth. Each of the plurality of pedestal structures 214 have a shape that corresponds to a shape of its corresponding adjustable base structure. For example, a shape of the first pedestal structure 214 a corresponds to a shape of the first adjustable base structure 124 a. More specifically, if the first adjustable base structure 124 has a ring-like shape, the first pedestal structure 214 a has a corresponding ring-like shape. In further embodiments, the plurality of pedestal structures 214 are laterally spaced form one another (e.g., via gaps).

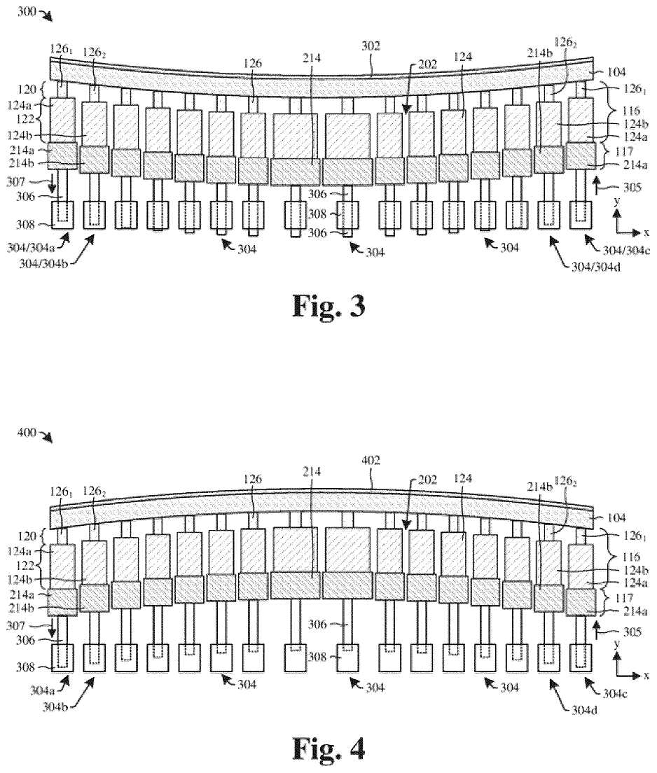

FIG. 3 illustrates a cross-sectional view 300 of some other embodiments of the adjustable wafer chuck 116.

As shown in the cross-sectional view 300 of FIG. 3, the wafer 104 is warped/bowed. The wafer 104 may be warped due to a first layer 302 being disposed/formed on the wafer 104. More specifically, the first layer 302 may be a compressive film that causes the wafer 104 to warp.

Also shown in the cross-sectional view 300 of FIG. 3, a plurality of actuators 304 are coupled to the plurality of adjustable base structures 124. In some embodiments, each of the actuators of the plurality of actuators 304 corresponds to one of the adjustable base structures 124. For example, a first actuator 304 a of the plurality of actuators 304 corresponds to the first adjustable base structure 124 a, a second actuator 304 b of the plurality of actuators 304 corresponds to the second adjustable base structure 124 b, and so forth. In further embodiments, multiple actuators correspond to a same adjustable base structure. For example, the first actuator 304 a and a third actuator 304 c of the plurality of actuators 304 correspond to the first adjustable base structure 124 a, the second actuator 304 b and a fourth actuator 304 d of the plurality of actuators 304 correspond to the second adjustable base structure 124 b, and so forth.

In some embodiments, the plurality of actuators 304 may be coupled to the plurality of adjustable base structures 124 via the plurality of pedestal structures 214. For example, the first actuator 304 a and the third actuator 304 c may be (directly) coupled (e.g., affixed) to the first pedestal structure 214 a, which is coupled to the first adjustable base structure 124 a; the second actuator 304 b and the fourth actuator 304 d may be (directly) coupled (e.g., affixed) to the second pedestal structure 214 b, which is coupled to the second adjustable base structure 124 b; and so forth. In other embodiments, the plurality of actuators 304 may be (directly) coupled to the plurality of adjustable base structures 124, or the plurality of actuators 304 may be coupled to the plurality of adjustable base structures 124 via some other structure(s).

The plurality of actuators 304 are configured to move their corresponding adjustable base structure along the plane (y-plane) in a first direction 305 (e.g., up) and a second direction 307 (e.g., down). For example, the first actuator 304 a and the third actuator 304 c are configured to move the first adjustable base structure 124 a along the plane (y-plane) in both the first direction 305 and the second direction 307; the second actuator 304 b and the fourth actuator 304 d are configured to move the second adjustable base structure 124 b along the plane (y-plane) in both the first direction 305 and the second direction 307; and so forth. The plurality of actuators 304 are configured to move their corresponding adjustable base structure along the plane (y-plane) so that each of the plurality of contact pads 126 are spaced about a same distance from the wafer 104 during a fabrication step (e.g., during a deposition process).

In some embodiments, the plurality of actuators 304 are configured to move their corresponding adjustable base structure independently along the plane (y-plane). For example, the first actuator 304 a and the third actuator 304 c are configured to move the first adjustable base structure 124 a along the plane (y-plane) in both the first and second directions independent of any of the other plurality of adjustable base structures 124 moving along the plane (y-plane); the second actuator 304 b and the fourth actuator 304 d are configured to move the second adjustable base structure 124 b along the plane (y-plane) in both the first and second directions independent of any of the other plurality of adjustable base structures 124 moving along the plane (y-plane); and so forth. In some embodiments, the plurality of actuators 304 may be, for example, an electric actuator, a pneumatic actuator, a hydraulic actuator, a linear actuator, some other suitable actuator, or a combination of the foregoing.

In some embodiments, each of the plurality of actuators 304 comprise an extension structure 306 (e.g., drive tube, piston, etc.) and a housing structure 308. The housing structure 308 is configured to be held in a fixed position, and the extension structure 306 is configured to move through the housing structure 308 along the plane (y-plane). The housing structure 308 comprises movement mechanisms (e.g., gears, magnets, screws, valves, etc.) that are configured to move the extension structure 306 in relation to the housing structure 308. The extension structure 306 of each of the plurality of actuators 304 is coupled to one or more of the plurality of adjustable base structures 124 (e.g., via the plurality of pedestal structures 214). As such, the plurality of actuators 304 may selectively move their corresponding adjustable base structure along the plane (y-plane) by selectively moving their extension structure 306.

FIG. 4 illustrates a cross-sectional view 400 of some other embodiments of the adjustable wafer chuck 116.

As shown in the cross-sectional view 400 of FIG. 4, the wafer 104 is warped/bowed in an opposite manner as the wafer in FIG. 3. The wafer 104 may be warped due to a second layer 402 being disposed/formed on the wafer 104. More specifically, the second layer 402 may be a tensile film that causes the wafer 104 to warp.

Because the plurality of actuators 304 are configured to move their corresponding adjustable base structure along the plane (y-plane) in both the first direction 305 and the second direction 307, regardless of the manner in which the wafer 104 is warped (e.g., convex or concave), the plurality of actuators 304 are able to move the plurality of adjustable base structures 124 so that each of the plurality of contact pads 126 are spaced about a same distance from the wafer 104 during a fabrication step (e.g., during a deposition process). It will be appreciated that, even if the wafer 104 is not warped, the plurality of actuators 304 are able to move the plurality of adjustable base structures 124 so that each of the plurality of contact pads 126 are spaced about a same distance from the wafer 104 during a fabrication step.

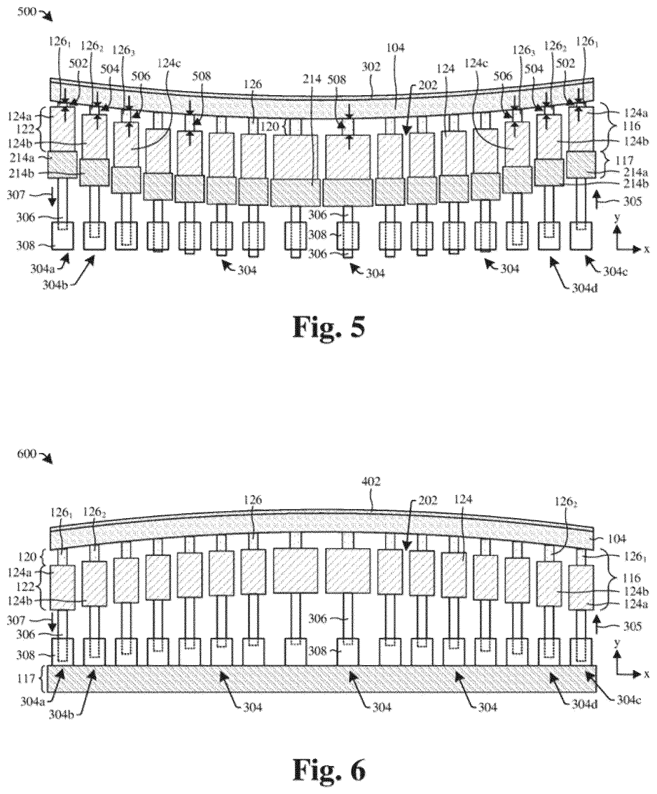

FIG. 5 illustrates a cross-sectional view 500 of some other embodiments of the adjustable wafer chuck 116.

As shown in the cross-sectional view 500 of FIG. 5, some of the contact pads of the plurality of contact pads 126 may have different heights than some other of the contact pads. For example, the plurality of groups of contact pads 126 ₁-126 ₃ comprises the first group of contact pads 126 ₁, the second group of contact pads 126 ₂, and a third group of contact pads 126 ₃. The third group of contact pads 126 ₃ comprises one or more third contact pads of the plurality of contact pads 126. In some embodiments, the contact pads of the third group of contact pads 126 ₃ are affixed to the third adjustable base structure 124 c. The contact pads of the first group of contact pads 126 ₁ have a first height 502, the contact pads of the second group of contact pads 126 ₂ have a second height 504, the contact pads of the third group of contact pads 126 ₃ have a third height 506, and the contact pads of the other groups of the plurality of groups of contact pads 126 ₁-126 ₃ have a fourth height 508.

In some embodiments, the fourth height 508 is different than the first height 502, the second height 504, and/or the third height 506. In some embodiments, the third height 506 is different than the first height 502, the second height 504, and/or the fourth height 508. In some embodiments, the second height 504 is different than the first height 502, the third height 506, and/or the fourth height 508. In some embodiments, the first height 502 is different than the second height 504, the third height 506, and/or the fourth height 508.

In some embodiments, the third height 506 is less than the fourth height 508. In some embodiments, the second height 504 is less than the third height 506. In some embodiments, the first height 502 is less than the second height 504. In some embodiments, the first height 502 may be between about 0.5 mm and about 4.9 mm. In further embodiments, the first height 502 may be between about 0.5 mm and about 1.5 mm. In yet further embodiments, the first height 502 may be about 1 mm. In some embodiments, the fourth height 508 may be between about 0.6 mm and about 5 mm. In further embodiments, the fourth height 508 may be between about 2.5 mm and about 3.5 mm. In yet further embodiments, the first height 502 may be about 3 mm. In further embodiments, the second height 504 is between the first height 502 and the third height 506. In yet further embodiments, the third height 506 is between the second height 504 and the fourth height 508.

Because the plurality of actuators 304 are configured to independently move their corresponding adjustable base structure along the plane (y-plane), even if the plurality of contact pads 126 have varying heights, the plurality of actuators 304 are able to move the plurality of adjustable base structures 124 so that each of the plurality of contact pads 126 are spaced about a same distance from the wafer 104 during a fabrication step (e.g., during a deposition process). In some embodiments, the plurality of contact pads 126 have varying heights due to the expected wear of the plurality of contact pads 126 (e.g., the outer contacts pads wearing at a faster rate than inner contact pads). In such embodiments, the adjustable wafer chuck 116 may have a longer lifespan than a typical wafer chuck (e.g., due to the adjustable wafer chuck 116 being able to compensate for the height variations). In other embodiments, the plurality of contact pads 126 have varying heights due to a process in which the plurality of contact pads 126 are formed (e.g., the process for depositing the plurality of contact pads 126 onto the plurality of adjustable base structures 124 may be relatively non-uniform). In such embodiments, in comparison to a typical wafer chuck (e.g., non-adjustable wafer chuck), the adjustable wafer chuck 116 may have improved initial performance (e.g., due to the adjustable wafer chuck 116 being able to compensate for the height variations).

FIG. 6 illustrates a cross-sectional view 600 of some other embodiments of the adjustable wafer chuck 116.

As shown in the cross-sectional view 600 of FIG. 6, in some embodiments, the plurality of actuators 304 are disposed between the chuck pedestal 117 and the plurality of adjustable base structures 124. In such embodiments, the chuck pedestal 117 may comprise a continuous structure in which each of the plurality of actuators 304 are disposed on. In other such embodiments, the chuck pedestal 117 may comprise the plurality of pedestal structures 214. In further embodiments, the housing structure 308 of each of the plurality of actuators 304 may be (directly) disposed on (e.g., affixed to) the chuck pedestal 117. In yet further embodiments, the extension structures of the plurality of actuators 304 may be (directly) coupled to (e.g., affixed to) the plurality of adjustable base structures 124.

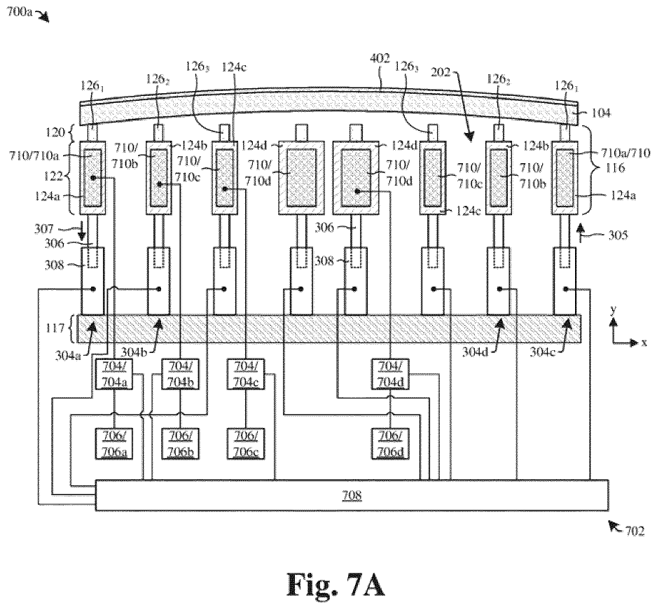

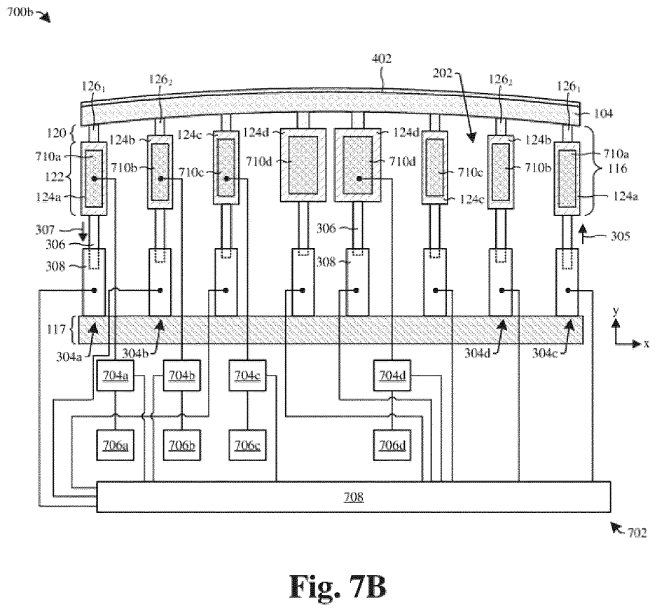

FIGS. 7A-7B illustrate diagrams 700 a-700 b of some embodiments of a system configured to operate some embodiments of the adjustable wafer chuck 116. More specifically, the diagram 700 a of FIG. 7A illustrates the system 702 before the adjustable wafer chuck 116 has been adjusted to a warped wafer, and the diagram 700 b of FIG. 7B illustrates the system 702 after the adjustable wafer chuck 116 has been adjusted to the shape of the warped wafer.

As shown in the diagrams 700 a-700 b of FIG. 7A-7B, the system 702 comprises the adjustable wafer chuck 116, the plurality of actuators 304, a plurality of sensors 704, a plurality of power supplies 706, and a controller 708. Also shown in the diagrams 700 a-700 b of FIG. 7A-7B, a plurality of chucking electrodes 710 are respectively disposed in the plurality of adjustable base structures 124. For example, the plurality of adjustable base structures 124 may comprise the first adjustable base structure 124 a, the second adjustable base structure 124 b, the third adjustable base structure 124 c, and a fourth adjustable base structure 124 d; and a first chucking electrode 710 a of the plurality of chucking electrodes 710 is disposed in the first adjustable base structure 124 a, a second chucking electrode 710 b of the plurality of chucking electrodes 710 is disposed in the second adjustable base structure 124 b, a third chucking electrode 710 c of the plurality of chucking electrodes 710 is disposed in the third adjustable base structure 124 c, and a fourth chucking electrode 710 d of the plurality of chucking electrodes 710 is disposed in the fourth adjustable base structure 124 d. In some embodiments, ESC circuitry (e.g., ESC circuitry 118) comprises the plurality of sensors 704, the plurality of power supplies 706, and/or the controller 708.

The plurality of power supplies 706 are electrically coupled to the plurality of chucking electrodes 710, respectively. For example, a first power supply 706 a of the plurality of power supplies 706 is electrically coupled to the first chucking electrode 710 a, a second power supply 706 b of the plurality of power supplies 706 is electrically coupled to the second chucking electrode 710 b, a third power supply 706 c of the plurality of power supplies 706 is electrically coupled to the third chucking electrode 710 c, and a fourth power supply 706 d of the plurality of power supplies 706 is electrically coupled to the fourth chucking electrode 710 d. The plurality of power supplies 706 are configured to provide power (e.g., an AC voltage signal, a DC voltage signal, etc.) to the plurality of chucking electrodes 710, respectively. For example, the first power supply 706 a is configured to provide a first power signal (e.g., AC voltage signal) to the first chucking electrode 710 a, the second power supply 706 b is configured to provide a second power signal (e.g., AC voltage signal) to the second chucking electrode 710 b, and so forth. In some embodiments, plurality of power supplies 706 are configured to respectively provide power to the plurality of chucking electrodes 710 to turn the adjustable wafer chuck “ON,” thereby electrostatically clamping the wafer 104 to the adjustable wafer chuck 116. In some embodiments, the plurality of power supplies 706 may be discrete power units. It will be appreciated that, in other embodiments, the plurality of power supplies 706 may be portions of a larger power supply unit.

The plurality of power supplies 706 are electrically coupled to the plurality of chucking electrodes 710 via a plurality of electrical connectors. The plurality of electrical connectors are configured to provide electrical connections between the plurality of chucking electrodes 710 and the plurality of power supplies 706. In some embodiments, the plurality of electrical connectors may be or comprise, for example, DC connectors, AC connectors, barrel connectors, USB sockets, pin and socket connectors, some other types of electrical connectors, or a combination of the foregoing.

Each electrical connector of the plurality of electrical connectors couples to one of the plurality of chucking electrodes 710. For example, a first electrical connector provides an electrical connection to the first chucking electrode 710 a, a second electrical connector provides an electrical connection to the second chucking electrode 710 b, and so forth. In some embodiments, each electrical connector of the plurality of electrical connectors provides an electrical connection between one of the plurality of chucking electrodes 710 and one of the plurality of power supplies 706. For example, the first electrical connector provides an electrical connection between the first chucking electrode 710 a and the first power supply 706 a, the second electrical connector provides an electrical connection between the second chucking electrode 710 b and the second power supply 706 b, and so forth. In other embodiments, some of the electrical connectors of the plurality of electrical connectors provide electrical connections between one of the plurality of chucking electrodes 710 and another one of the plurality of chucking electrodes 710 (e.g., the electrical connectors may be configured so that the chucking electrodes are electrically coupled to a power supply in a daisy-chain manner). For example, the first electrical connector provides an electrical connection between the first chucking electrode 710 a and the first power supply 706 a, the second electrical connector provides an electrical connection between the first chucking electrode 710 a and the second chucking electrode 710 b, a third electrical connector provides an electrical connection between the second chucking electrode 710 b and the third chucking electrode 710 c, and so forth.

In some embodiments, the plurality of electrical connectors allow the plurality of adjustable base structures 124 to move along the plane (y-plane). For example, because the plurality of adjustable base structures 124 are configured to move along the plane (y-plane), some physical connections (e.g., a solid conductive structures disposed and extending laterally through a chuck) would not provide the means for the adjustable base structures 124 to move along the plane (y-plane) (e.g., the solid conductive structure would break if the adjustable base structures 124 moved along the plane). Thus, by having the plurality of electrical connectors, the adjustable base structures 124 may be able to move freely along the plane (y-plane) while maintaining electrical connections between the plurality of power supplies 706 and the plurality of chucking electrodes 710.

The plurality of sensors 704 are electrically coupled to the controller 708. The plurality of sensors 704 are configured to determine the distances in which the plurality of contact pads 126 are spaced from a surface (e.g., lower surface) of the wafer 104. In some embodiments, the plurality of sensors 704 are configured to determine the distances in which the plurality of chucking electrodes 710 are spaced from the surface of the wafer 104. The plurality of sensors 704 may be or comprise, for example, electrical sensors (e.g., voltage sensors, current sensors, etc.), capacitive sensors (e.g., proximity sensors), time-of-flight sensors, a ranging sensor, a force sensor, a pressure sensor, some other type of sensor, or a combination of the foregoing.

In some embodiments, the plurality of sensors 704 are configured to determine the distances in which the plurality of contact pads 126 are spaced from the surface of the wafer 104 by determining the distances in which the plurality of chucking electrodes 710 are spaced from the surface of the wafer 104. For example, a first sensor 704 a of the plurality of sensors 704 is configured to determine a distance in which the first chucking electrode 710 a is spaced from a lower surface of the wafer 104, a second sensor 704 b of the plurality of sensors 704 is configured to determine a distance in which the second chucking electrode 710 b is spaced from the lower surface of the wafer 104, a third sensor 704 c of the plurality of sensors 704 is configured to determine a distance in which the third chucking electrode 710 c is spaced from the lower surface of the wafer 104, and a fourth sensor 704 d of the plurality of sensors 704 is configured to determine a distance in which the fourth chucking electrode 710 d is spaced from the lower surface of the wafer 104.

The plurality of sensors 704 are configured to respectively generate a first plurality of electrical signals that correspond to the distances in which the plurality of chucking electrodes 710 are spaced from the surface of the wafer 104. For example, as shown in the diagram 700 a of FIG. 7A, the first chucking electrode 710 a is spaced from the lower surface of the wafer 104 by a first distance (e.g., 10 mm), the second chucking electrode 710 b is spaced from the lower surface of the wafer 104 by a second distance (e.g., 10.5 mm), the third chucking electrode 710 c is spaced from the bottom surface of the wafer 104 by a third distance (e.g., 11 mm), and so forth. As such, the first sensor 704 a generates a first electrical signal that corresponds to the first distance, the second sensor 704 b generates a second electrical signal that corresponds to the second distance, the third sensor 704 c generates a third electrical signal that corresponds to the third distance, and so forth. The plurality of sensors 704 are configured to provide the first plurality of electrical signals to the controller 708.

It will be appreciated that the first plurality of electrical signals that correspond to the distances in which the plurality of chucking electrodes 710 are spaced from the surface of the wafer 104 may also translate to the distances in which the plurality of contact pads 126 are spaced from a surface of the wafer 104. For example, the distances in which the plurality of chucking electrodes 710 are spaced from the surface of the wafer 104 may be translated to the distances in which the plurality of contact pads 126 are spaced from a surface of the wafer 104 by factoring in the distances in which the plurality of contact pads 126 are respectively spaced from the plurality of chucking electrodes 710. In such embodiments, the controller 708 may be configured to factor in the distances in which the plurality of contact pads 126 are respectively spaced from the plurality of chucking electrodes 710.

In some embodiments, the plurality of sensors 704 are configured to determine the distances in which the plurality of chucking electrodes 710 are spaced from the surface of the wafer 104 by measuring the electrical resistances between the plurality of chucking electrodes 710 and the plurality of power supplies 706. For example, the first sensor 704 a is configured to determine an electrical resistance between the first chucking electrode 710 a and the first power supply 706 a, the second sensor 704 b is configured to determine an electrical resistance between the second chucking electrode 710 b and the second power supply 706 b, and so forth. In further embodiments, the plurality of sensors 704 are electrically coupled between their corresponding chucking electrode and their corresponding power supply. For example, the first sensor 704 a is electrically coupled between the first chucking electrode 710 a and the first power supply 706 a (e.g., electrically coupled along an electrical connection (e.g., wire) between the first chucking electrode 710 a and the first power supply 706 a), the second sensor 704 b is electrically coupled between the second chucking electrode 710 b and the second power supply 706 b, and so forth.

The controller 708 is configured to receive the first plurality of electrical signals from the plurality of sensors 704. In some embodiments, the controller 708 is configured to generate a second plurality of electrical signals based on the first plurality of electrical signals. For example, the controller 708 receives the first electrical signal from the first sensor 704 a and generates a fourth electrical signal that corresponds to the first electrical signal, the controller 708 receives the second electrical signal from the second sensor 704 b and generates a fifth electrical signal that corresponds to the second electrical signal, the controller 708 receives the third electrical signal from the third sensor 704 c and generates a sixth electrical signal that corresponds to the third electrical signal, and so forth. In further embodiments, the controller 708 is configured to provide the second plurality of electrical signals to the plurality of actuators 304. For example, the controller 708 is configured to provide the fourth electrical signal to the first actuator 304 a, the controller 708 is configured to provide the fifth electrical signal to the second actuator 304 b, the controller 708 is configured to provide the sixth electrical signal to the third actuator 304c, and so forth.

The plurality of actuators 304 are configured to receive the second plurality of electrical signals. As shown in the diagram 700 b of FIG. 7B, the plurality of actuators 304 are configured to move their corresponding extension structure 306 in response to receiving the second plurality of electrical signals, which moves their corresponding adjustable base structure a predefined distance. As such, the distances in which the plurality of contact pads 126 are spaced from the surface of the wafer 104 may be reduced. In other words, the adjustable wafer chuck 116 is adjusted to compensate for a warped wafer by reducing the distances in which the plurality of contact pads 126 are spaced from the surface of the wafer 104. It will also be appreciated that the plurality of actuators 304 are configured to move their corresponding extension structure 306 to increase the distances in which the plurality of contact pads 126 are spaced from the surface of the wafer 104. In other words, the adjustable wafer chuck 116 is adjusted to compensate for a warped wafer by reducing and/or increasing the distances in which the plurality of contact pads 126 are spaced from the surface of the wafer 104.

For example, the first sensor 704 a provides the first electrical signal to the controller 708 and the second sensor 704 b provides the second electrical signal to the controller 708. The controller 708 may analyze the first electrical signal to determine the distance in which the first group of contact pads 126 ₁ are spaced from the warped wafer (e.g., 0 mm, as shown in the diagram 7A of FIG. 7A), and the controller 708 may analyze the second electrical signal to determine the distance in which the second group of contact pads 126 ₂ are spaced from the warped wafer (e.g., 0.5 mm, as shown in the diagram 7A of FIG. 7A).

In some embodiments, the controller 708 generates a fourth electrical signal that corresponds to the first electrical signal and provides the fourth electrical signal to the first actuator 304 a and generates a seventh electrical signal that corresponds to the first electrical signal and provides the seventh electrical signal to the third actuator 304 c. In other embodiments, if the controller 708 analyzes the first and second electrical signals and determines that one of the electrical signals (e.g., the first electrical signal) indicates that one of the plurality of groups of contact pads 126 ₁-126 ₃ (e.g., the first group of contact pads 126 ₁) are already within a predefined range (e.g., 0 mm to 0.2 mm), the controller 708 may not provide an electrical signal to the either of the first actuator 304 a or the third actuator 304 c (e.g., an electrical signal may not need to be provided to either of these actuators because they do not need to adjust their corresponding adjustable base structure to move it closer to (or further away from) the lower surface of the wafer 104). In some embodiments, the controller 708 generates a fifth electrical signal that corresponds to the second electrical signal and provides the fifth electrical signal to the second actuator 304 b and generates an eighth electrical signal that corresponds to the second electrical signal and provides the eighth electrical signal to the fourth actuator 304 d. In response to receiving the fifth electrical signal and the eighth electrical signal, the second actuator 304 b and the fourth actuator 304 d move their corresponding extension structure 306 a corresponding distance, which moves the second adjustable base structure 124 b along the plane (y-plane) a predefined distance (e.g., 0.5 mm in the first direction 305). As a result, the distance in which the second group of contact pads 126 ₂ is spaced may be reduced (or increased).

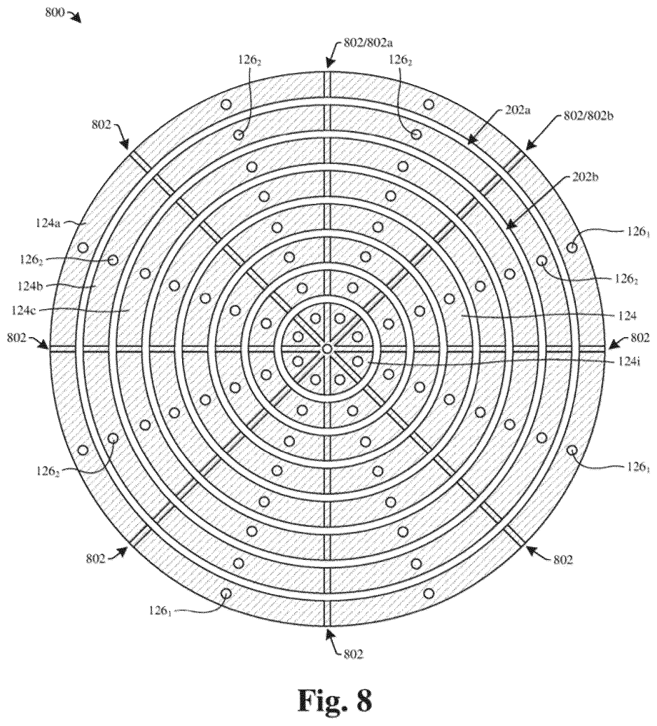

FIG. 8 illustrates a top view 800 of some other embodiments of the adjustable wafer chuck 116.

As shown in the top view 800 of FIG. 8, a plurality of grooves 802 may be disposed in the plurality of adjustable base structures 124. For example, a first groove 802 a may be disposed in the plurality of adjustable base structures 124, a second groove 802 b may be disposed in the plurality of adjustable base structures 124, and so forth. In some embodiments, the plurality of grooves 802 are configured to direct the flow of processing gases (e.g., argon (Ar)) through the adjustable wafer chuck 116.

Also shown in the top view 800 of FIG. 8, the plurality of grooves 802 are defined by a plurality of sub-groove structures disposed in the plurality of adjustable base structures 124. For example, the first groove 802 a is defined by a first sub-groove structure disposed in the first adjustable base structure 124 a, a first sub-groove structure disposed in the second adjustable base structure 124 b, a first sub-groove structure disposed in the third adjustable base structure 124 c, and so forth; and the second groove 802 b is defined by a second sub-groove structure disposed in the first adjustable base structure 124 a, a second sub-groove structure disposed in the second adjustable base structure 124 b, a second sub-groove structure disposed in the third adjustable base structure 124 c, and so forth.

In some embodiments, the plurality of sub-groove structures are aligned, such that the plurality of grooves 802 extend radially in predefined directions away from a center point of the innermost adjustable base structure 124 i (e.g., the plurality of grooves 802 extend along radial planes that intersect the center point of the innermost adjustable base structure 124 i). For example, the first sub-groove structures disposed in the plurality of adjustable base structures 124 are aligned so that the first groove 802 a extends radially in a first direction from the center point of the innermost adjustable base structure 124 i, the second sub-groove structures disposed in the plurality of adjustable base structures 124 are aligned so that the second groove 802 b extends radially in a second direction (e.g., rotated about 45 degrees from the first direction) from the center point of the innermost adjustable base structure 124 i, and so forth.

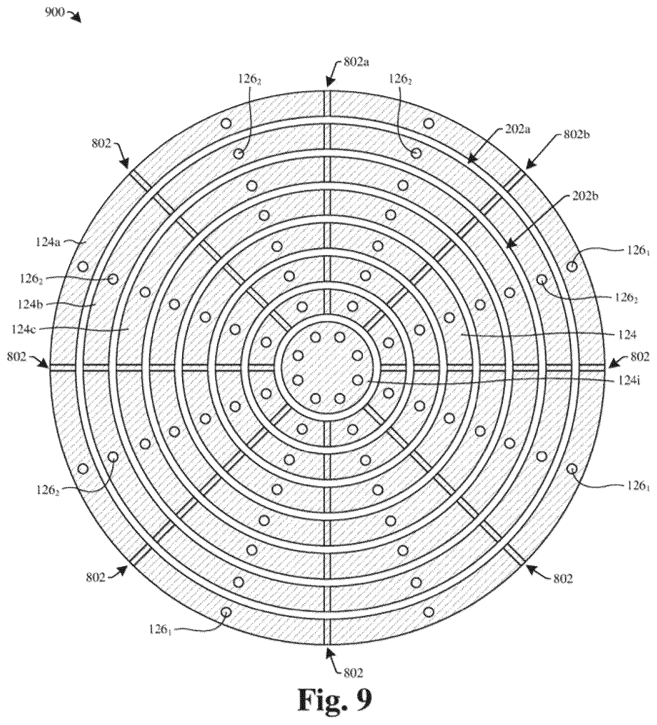

FIG. 9 illustrates a top view 900 of some other embodiments of the adjustable wafer chuck 116.

As shown in the top view 900 of FIG. 9, in some embodiments, the innermost adjustable base structure 124 i may have a disc-like shape (instead of a ring-like shape). Also shown in top view 900 of FIG. 9, in some embodiments, the plurality of grooves 802 may be disposed in each of the plurality of adjustable base structures 124 except the innermost adjustable base structure 124 i.

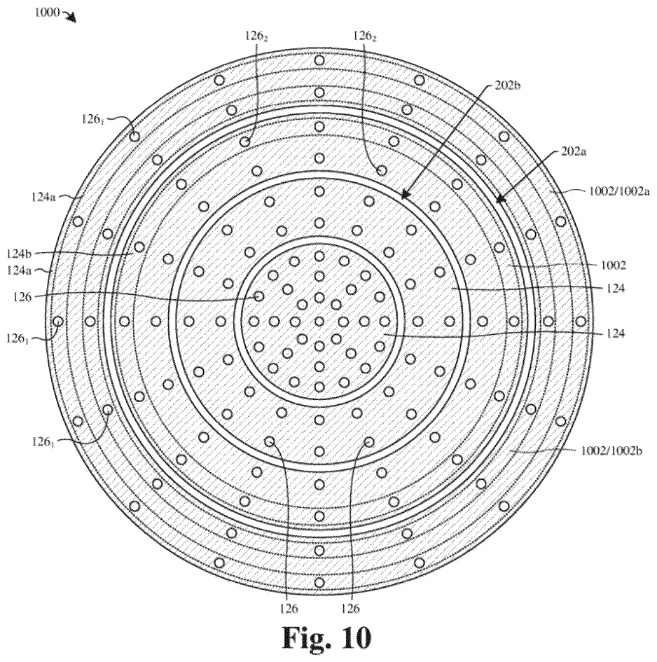

FIG. 10 illustrates a top view 1000 of some other embodiments of the adjustable wafer chuck 116.

As shown in the top view 1000 of FIG. 10, in some embodiments, one or more of the groups of contact pads 126 ₁-126 ₂ comprises a plurality of rows of contact pads 1002 a-1002 b. For example, the first group of contact pads 126 ₁ comprises a first row of contact pads 1002 a and a second row of contact pads 1002 b. In some embodiments, the rows of the plurality of rows of contact pads 1002 a-1002 b are concentric rows, as illustrated in the top view 1000 of FIG. 10. While the top view 1000 of FIG. 10 illustrates the first group of contact pads 126 ₁ comprising two rows of contacts pads, it will be appreciated that the first group of contact pads 126 ₁ (and/or any other of the one or more of the groups of contact pads 126 ₁-126 ₂) may comprise any number of rows of contact pads (e.g., three rows, four rows, five rows, etc.). For clarity in the figures, only some of the plurality of rows of contact pads 1002 a-1002 b are labeled in FIG. 10.

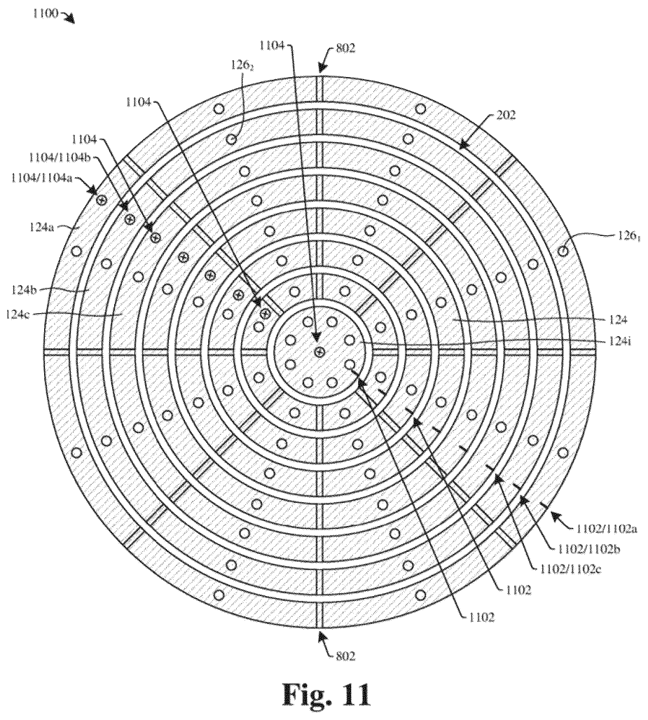

FIG. 11 illustrates a top view 1100 of some other embodiments of the adjustable wafer chuck 116.

As shown in the top view 1100 of FIG. 11, in some embodiments, a first plurality of alignment indicators 1102 may be disposed on the plurality of adjustable base structures 124, respectively. For example, a first alignment indicator 1102 a is disposed on the first adjustable base structure 124 a, a second alignment indicator 1102 b is disposed on the second adjustable base structure 124 b, a third alignment indicator 1102 c is disposed on the third adjustable base structure 124 c, and so forth. In some embodiments, the first plurality of alignment indicators 1102 may be structures disposed in the plurality of adjustable base structures 124 (e.g., indicator structures (such as an arrows, divots, lines, grooves, etc.) embossed into the adjustable base structures). In other embodiments, the first plurality of alignment indicators 1102 may be structures disposed on the plurality of adjustable base structures 124 (e.g., indicator structures (such as an arrows, bumps, lines, grooves, etc.) that protrude from (or are disposed on surfaces of) the adjustable base structures). The first plurality of alignment indicators 1102 are utilized (e.g., by a user) to align the adjustable base structures 124 in a predefined manner. For example, the first plurality of alignment indicators 1102 allow a user to easily align the adjustable base structures 124 so that the sub-groove structures are appropriately aligned along their corresponding radial plane.

Also shown in the top view 1100 of FIG. 11, in some embodiments, a plurality of fastening structures 1104 are disposed on/in the plurality of adjustable base structures 124, respectively. In some embodiments, the plurality of fastening structures 1104 may be, for example, bolt-type fasteners, screw-type fasteners, pin-type fasteners, clamp-like fasteners, some other type of fasteners, or a combination of the foregoing. The plurality of fastening structures 1104 are configured to fasten the plurality of adjustable base structures 124 to a mounting structure. For example, in some embodiments, the mounting structure may be a chuck pedestal 117 comprising a plurality of pedestal structures 214 (see, e.g., FIGS. 2A-2B). The plurality of pedestal structures 214 comprises a first pedestal structure 214 a, a second pedestal structure 214 b, and so forth. A first fastening structure 1104 a (e.g., machine screw) engages the first adjustable base structure 124 a (e.g., via threads in the first adjustable base structure 124 a) and fastens the first adjustable base structure 124 a to the first pedestal structure 214 a (e.g., via threads in the first pedestal structure 214 a); a second fastening structure 1104 b engages the second adjustable base structure 124 b and fastens the second adjustable base structure 124 b to the second pedestal structure 214 b; and so forth.

Because the adjustable wafer chuck 116 comprises the first plurality of alignment indicators 1102 and/or because the adjustable wafer chuck 116 is configured to be fastened via the plurality of fastening structures 1104, the adjustable wafer chuck 116 may be easier to repair than a typical wafer chuck. For example, once the plurality of contact pads of a typical wafer chuck reaches a predetermined amount of wear, the entire wafer chuck may have to be removed from its processing chamber (even though some portions of the typical wafer chuck are still in good working condition) and sent to a specialized processing facility to repair the plurality of contact pads on the typical wafer chuck. On the other hand, once the plurality of contact pads 126 reach a predetermined level of wear, a user may simply unfasten one or more of the plurality of adjustable base structures 124 and replace them with new adjustable base structures. Accordingly, the adjustable wafer chuck 116 may decrease a cost to fabricate ICs (e.g., by reducing downtime, reducing repair cost, reducing material waste, etc.).

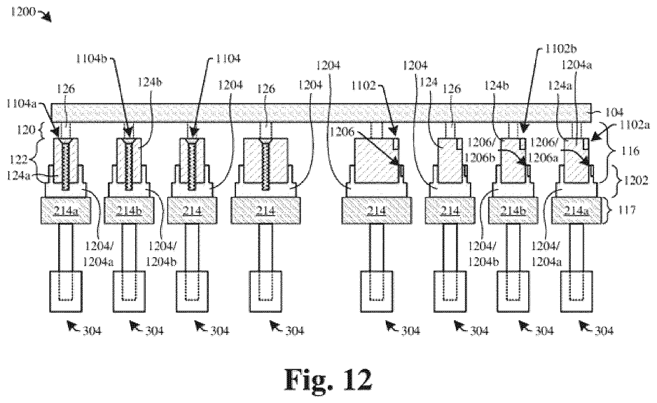

FIG. 12 illustrates a cross-sectional view 1200 of some embodiments of the adjustable wafer chuck 116.

As shown in the cross-sectional view 1200 of FIG. 12, a support structure 1202 is disposed between the chuck pedestal 117 and the plurality of adjustable base structures 124. The support structure 1202 is affixed to the chuck pedestal 117. In some embodiments, the support structure 1202 may comprise a plurality of individual support structures 1204. For example, the support structure 1202 may comprise a first individual support structure 1204 a, a second individual support structure 1204 b, and so forth. In some embodiments, the plurality of individual support structures 1204 are respectively disposed on (e.g., affixed to) the plurality of pedestal structures 214. For example, the first individual support structure 1204 a is disposed on the first pedestal structure 214 a, the second individual support structure 1204 b is disposed on the second pedestal structure 214 b, and so forth.

The plurality of adjustable base structures 124 are configured to engage the support structure 1202. In some embodiments, the plurality of adjustable base structures 124 are configured to engage the plurality of individual support structures 1204, respectively. For example, the first adjustable base structure 124 a is configured to engage the first individual support structure 1204 a, the second adjustable base structure 124 b is configured to engage the second individual support structure 1204 b, and so forth.

In further embodiments, the plurality of adjustable base structures 124 are configured to be fastened to the support structure 1202 via the plurality of fastening structures 1104 (e.g., the plurality of fastening structures 1104 engaging threads disposed in the support structure 1202). In other words, the support structure 1202 may be the mounting structure (e.g., the structure in which the plurality of adjustable base structures 124 are fastened to via the plurality of fastening structures 1104). In yet further embodiments, the plurality of adjustable base structures 124 are configured to be fastened to the plurality of individual support structures 1204, respectively. For example, the first adjustable base structure 124 a is configured to be fastened to the first individual support structure 1204 a via the first fastening structure 1104 a, the second adjustable base structure 124 b is configured to be fastened to the second individual support structure 1204 b via the second fastening structure 1104 b, and so forth.

Also shown in the cross-sectional view 1200 of FIG. 12, in some embodiments, a second plurality of alignment indicators 1206 may be disposed in/on the support structure 1202. In further embodiments, the second plurality of alignment indicators 1206 may be disposed on the plurality of individual support structures 1204, respectively. For example, a fourth alignment indicator 1206 a is disposed on the first individual support structure 1204 a, a fifth alignment indicator 1206 b is disposed on the second individual support structure 1204 b, and so forth. In some embodiments, the second plurality of alignment indicators 1206 may be structures disposed in the plurality of individual support structures 1204 (e.g., indicator structures (such as an arrows, divots, lines, grooves, etc.) embossed into the individual support structures). In other embodiments, the second plurality of alignment indicators 1206 may be structures disposed on the plurality of individual support structures 1204 (e.g., indicator structures (such as an arrows, bumps, lines, grooves, etc.) that protrude from (or are disposed on surfaces of) the individual support structures).

The first plurality of alignment indicators 1102 and the second plurality of alignment indicators 1206 may be utilized (e.g., by a user) to align the adjustable base structures 124 in a predefined manner. For example, by aligning the first plurality of alignment indicators 1102 with the second plurality of alignment indicators 1206, respectively, the adjustable base structures 124 may be aligned so that the sub-groove structures are appropriately aligned along their corresponding radial plane. While the cross-sectional view 1200 of FIG. 12 illustrates the second plurality of alignment indicators 1206 disposed in the support structure 1202, it will be appreciated that, in other embodiments, the second plurality of alignment indicators 1206 may be disposed on/in the chuck pedestal (e.g., in embodiments in which the mounting structure is the chuck pedestal 117).

Embodiments herein may provide for forming a tunnel oxide layer, i.e., a layer of a metal oxide, such as aluminum oxide (AlO), magnesium oxide (MgO), strontium oxide (SrO), iron oxide (Fe2O3), nickel oxide (NiO), cobalt oxide (CoO), manganese oxide (MnO2), or other suitable oxide layer for use as a barrier layer. For example, such an oxide layer may be formed as a portion of a magnetoresistive random-access memory (MRAM), such as a magnetic-tunnel junction (MTJ). To form an oxide layer with the process tool 100, the process tool is designed to introduce oxygen to the wafer or workpiece.

Referring back to FIG. 1A, the process tool 100 further includes a shutter tube 130 for flowing a gas 132 into chamber housing 102. For example, in certain embodiments, it may be desirable to deposit or form a layer of metal oxide. In such embodiments, the shutter tube 130 may introduce oxygen 132 into the chamber housing 102.

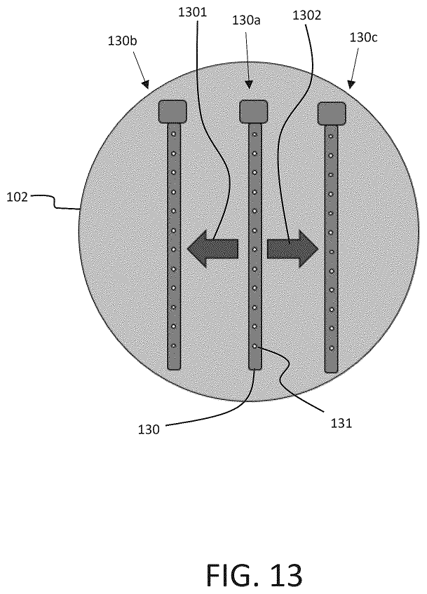

FIG. 13 is a bottom view of the shutter tube 130 within the chamber housing 120. As shown, the shutter tube 130 include a plurality of opening 131 through which the gas 132 may be directed into the chamber housing 120, and more specifically toward the wafer 104. The openings 131 may be spaced from one another along the length of the shutter tube 130.

FIG. 13 illustrates the shutter tube 130 at an initial location 130a. Embodiments herein provide for moving the shutter tube laterally in the direction of arrow 1301 to a second location 130b and/or laterally in the direction of arrow 1302 to a third location 130c, or to locations between second location 130b and third location 130c. In certain embodiments, the initial location 130 a and the second location 130 b are up to 25 millimeters apart. Further, in certain embodiments, the initial location 130 a and the third location 130 c are up to 25 millimeters apart.

In certain embodiments, the location and flow rate of the shutter tube 130 is controlled to form the oxide layer with a uniform thickness. For example, the shutter tube 130 may be controlled to adjust a ratio of the percentage of oxygen at an edge region of the wafer to the percentage of oxygen at a central region of the wafer. As a result, rates of formation of the oxide layer at the edge region and central region may be controlled with respect to one another.

The process tool 100 may be provided with a PID (Proportional-Integral-Derivative) controller or control module 140. Control module 140 may be part of or include controller 708.

The module 140 may be located inside and/or outside of the chamber housing 102. As used herein, the term module refers to any hardware, software, firmware, electronic control unit or component, processing logic, and/or processor device, individually or in any combination, including without limitation: application specific integrated circuit (ASIC), an electronic circuit, a processor (shared, dedicated, or group) and memory that executes one or more software or firmware programs, a combinational logic circuit, and/or other suitable components that provide the described functionality. Embodiments of the present disclosure may be described herein in terms of functional and/or logical block components and various processing steps. It should be appreciated that such block components may be realized by any number of hardware, software, and/or firmware components configured to perform the specified functions. For example, an embodiment of the present disclosure may employ various integrated circuit components, e.g., memory elements, digital signal processing elements, logic elements, look-up tables, or the like, which may carry out a variety of functions under the control of one or more microprocessors or other control devices. For the sake of brevity, conventional techniques related to signal processing, data transmission, signaling, control, and other functional aspects of the systems (and the individual operating components of the systems) may not be described in detail herein.

The control module 140 may monitor, detect, record, and/or analyze electrostatic accumulation, which can present issues during deposition processes. For example, wafers can accumulate static charge during processing, especially in vacuum environments. This can lead to uneven electric fields that affect the deposition uniformity and quality. Electrostatic charges can cause defects in the thin films, such as pinholes or non-uniform thickness, which may degrade the performance of the deposited layers. Further, unwanted electric fields generated by electrostatic charges can interfere with the transport of ions or atoms during deposition, potentially impacting the deposition rate and film characteristics.

The control module 140 may further detect, record, and/or analyze a second harmonic wave. During deposition, the deposited layer may exhibit an electric field induced second harmonic generation effect.

The module 140 may control the location of the shutter tube 130 and/or the flow rate of oxygen from the shutter tube 130 in order to change process conditions to modulate second harmonic wave generation and/or other conditions that would affect uniformity of the deposited film. In addition to controlling the shutter tube 130, the module 140 may control the adjustable wafer chuck 116.

The shape of the wafer chuck 116 can influence the thickness of the deposited layer during deposition processes. For example, the geometry of the chuck affects how uniformly the electrostatic force is distributed across the substrate. A well-designed shape can create a more even electric field, helping to hold the substrate uniformly and ensuring consistent deposition across its surface.

The shape of the wafer chuck 116 can influence how closely the substrate is positioned relative to the source of the depositing material. Variations in height or contour can affect the angle of incidence of the material, leading to differences in thickness.

The design of the wafer chuck 116 may impact the flow of process gases (e.g., inert or reactive gases) over the substrate. A shape that promotes better gas distribution can help maintain uniform deposition conditions, contributing to consistent layer thickness.

The shape of the wafer chuck 116 can also influence thermal contact between the substrate and the chuck. Effective thermal management is crucial, as temperature variations can affect the deposition rate and, subsequently, layer thickness.

Depending on the shape and size of the wafer chuck 116, edge effects may occur, leading to non-uniform deposition near the edges of the substrate. This is particularly relevant in large-area coatings.

Thus, changing the shape of the wafer chuck 116 can influence electrostatic accumulation and its effects during deposition processes.

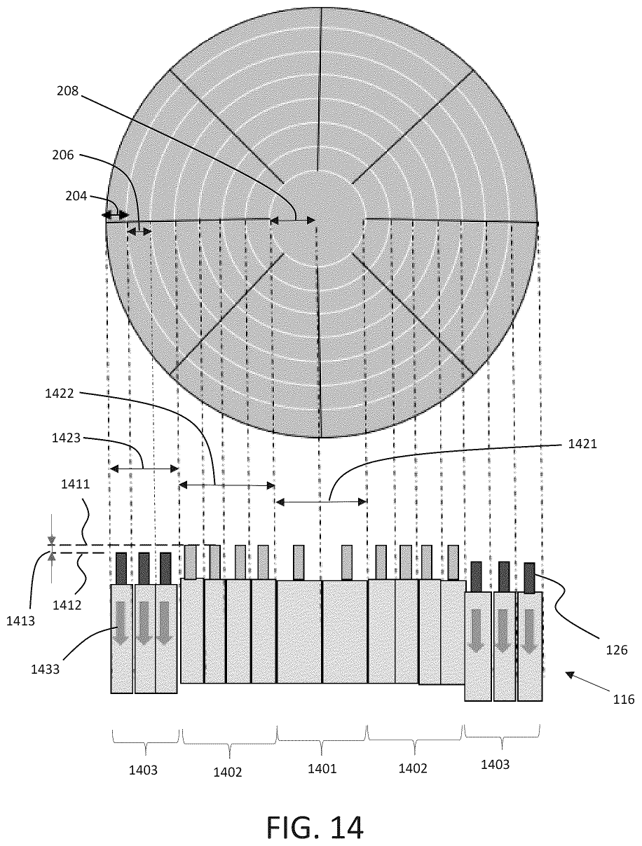

Referring to FIG. 14, a top view and cross sectional view illustrate the adjustable wafer chuck 116. As shown, contact pads 126 in a central region 1401 and an intermediate region 1402 of the wafer chuck 116 are at an initial height 1411. Further, contact pads 126 at an edge region 1403 of the wafer chuck 116 are lowered to second height 1412 in the direction of arrow 1433. As shown, a distance 1413 is defined between height 1411 and height 1412. In certain embodiments, the distance 1413 is plus or minus five (5) millimeters, i.e., contact pads 126 may be raised or lowered by up to five (5) millimeters. The heights of the contact pads 126 may be adjusted as described above.

As shown, the central region 1421 of contact pads 126 has a width or diameter 1421. Further, the intermediate region 1402 of contact pads 126 has a width or annular radius 1422. Also, the edge region 1403 of contact pads 126 has a width or annular radius 1423.

The width 1421 of the central region 1401 is equal to twice the third thickness 208. For example, width 1421 may be from 2 millimeters (mm) to 300 mm, including all values and ranges therein, such as from 50 mm to 70 mm, such as 60 mm.

In the illustrated embodiment, the intermediate region 1402 includes four contact pads 126, and the edge region 1423 includes three contact pads 126. However, other arrangements are contemplated, i.e., each region may include more or fewer contact pads 126. Each contact pad 126 in intermediate region 1422 and edge region 1423 has a thickness 204 or thickness 206 of from 1 mm to 150 mm, including all values and ranges therein, such as from 25 mm to 35 mm, such as 30 mm (+/−5 mm).

Thus, the illustrated intermediate region 1402 may have a width 1422 of from 4 mm to 600 mm, including all values and ranges therein, such as from 100 to 140 mm, such as 120 mm. Further, the illustrated edge region 1403 may have width 1423 of from 3 mm to 450 mm, including all values and ranges therein, such as from 75 mm to 105 mm, such as 90 mm.

In certain embodiments, thickness 206 is equal to thickness 204. In certain embodiments, thickness 206 is greater than thickness 204. A ratio of thickness 206 to thickness 204 is from 1:1 to 1:150, including all values and ranges therein.

In certain embodiments, thickness 206 is equal to thickness 208. In certain embodiments, thickness 206 is greater than thickness 208. A ratio of thickness 206 to thickness 208 is from 1:1 to 1:150, including all values and ranges therein.

The locations of the contact pads 126 and wafer chuck 116 may control the concentration of oxygen in the chamber adjacent to the wafer. Thus, height adjustment of the contact pads 126 may be used in order to change process conditions to modulate second harmonic wave generation and/or other conditions that would affect uniformity of the deposited film.

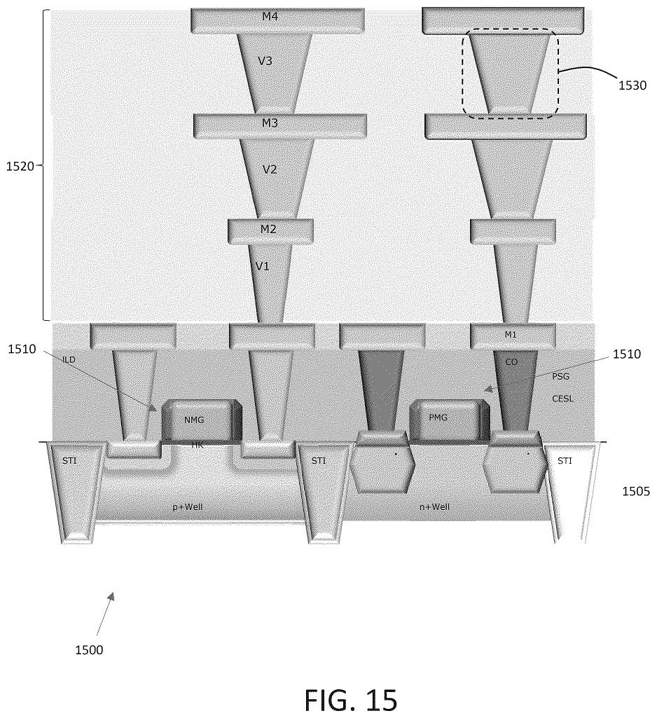

FIG. 15 illustrates a portion of a semiconductor structure 1500. As shown, gate structures 1510 are formed over a substrate 1505. Further, a metal interconnect structure 1520 is formed over the gate structures 1510.

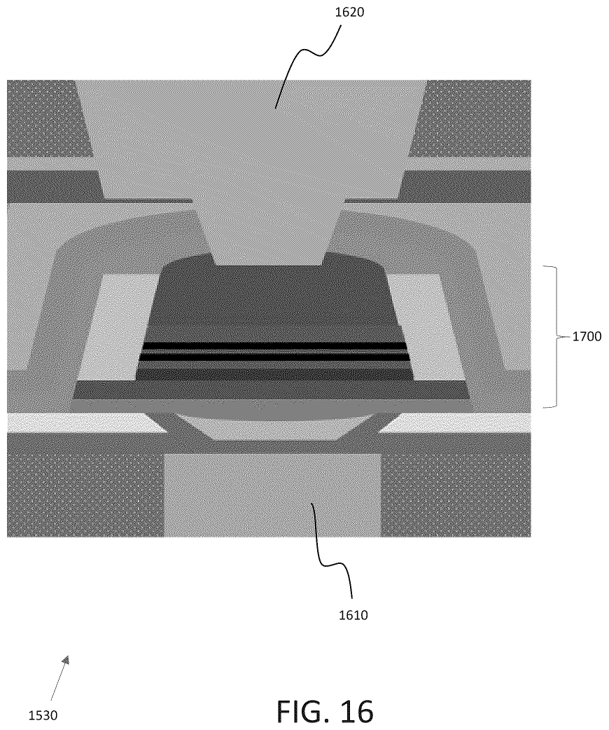

FIG. 16 provides a focused view of a portion 1530 of semiconductor structure 1500 shown in FIG. 15. As shown in FIG. 16, portion 1530 includes a lower metal layer 1610 and an upper metal layer 1620. Formed between the metal layers 1610 and 1620 is a magnetic-tunnel junction (MTJ) film stack1700.

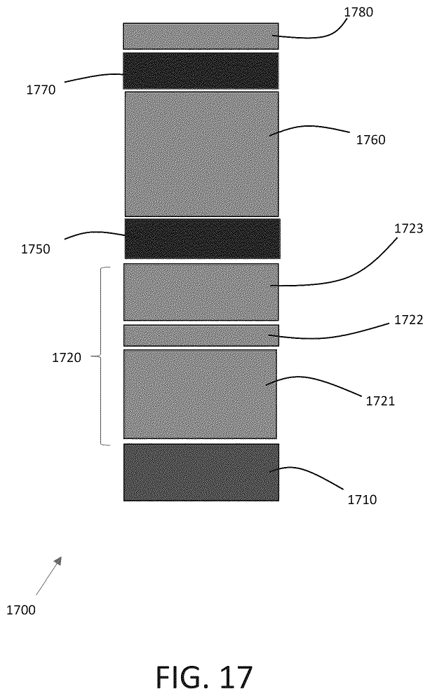

FIG. 17 illustrates the MTJ film stack 1700. As shown, the MTJ film stack 1700 includes a seed layer 1710. The seed layer 1710 may be tantalum nitride (TaN), iron boride (FeB), and/or nickel chromium (NiCr).

Formed over the seed layer 1710 is a pin layer 1720. Pin layer 1720 may include layers of nickel (Ni), cobalt (Co), ruthenium (Ru), iridium (Ir), cobalt-iron-boron (CoFeB), and/or iron (Fe), such as in the formation of a second anti-parallel (AP) layer (AP2) 1721, a spacer layer 1722, and a first anti-parallel (AP) layer (AP1) 1723.

Formed about the pin layer 1720 is a barrier layer 1750. Barrier layer 1750 may be a metal and/or metal oxide, such as is formed according to embodiments of the process tool 100 described above.

As shown, a free layer 1760 is formed over the barrier layer 1750. The free layer 1760 may include iron boride (FeB), molybdenum (Mo), chromium (Cr), and/or tungsten (W).

A cap layer 1770 is formed over the free layer 1760. The cap layer 1770 may be a metal and/or metal oxide, such as is formed according to embodiments of the process tool 100 described above.

As shown, a buffer layer or hard mask layer 1780 is formed over the cap layer 1770. The buffer layer 1780 may include molybdenum (Mo), iridium (Ir), ruthenium (Ru), and/or cobalt-iron-boron (CoFeB).

In order to optimize performance of the MTJ film stack 1700, the layers 1750 and 1770 may be formed with uniform deposition to form crystalline structures rather than amorphous structures. As a result, magnetoresistance (MR) performance is improved.

Thus, embodiments herein form metal oxide layers, such as layers 1750 and 1770, with improved uniformity in order to improve magnetoresistance (MR) performance of the MTJ. For example, tunneling effect and electric motor spin detection may be improved by the improved uniformity of the metal oxide layers. Further, the work function of the MTJ film stack may be improved by the improved uniformity of the metal oxide layers.

In certain embodiments, layer 1750 or layer 1770 may be formed as multi-film structures with layers metal oxide having high oxide percentages, and layers of metal oxide having low oxide percentages. By controlling the shutter tube 130 and the adjustable wafer chuck 116, the percentage of oxide formed in the metal oxide sublayers may be precisely controlled.

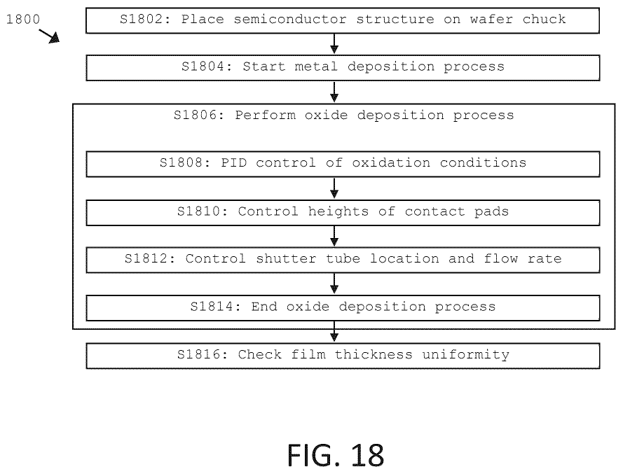

FIG. 18 illustrates a method 1800 for forming an oxide layer, such as in an MTJ film stack. As shown, method 1800 includes at, act S1802, placing a semiconductor structure (e.g., the wafer 104) on a wafer chuck (e.g., adjustable wafer chuck 116). The adjustable wafer chuck may include an adjustable base structure and contact pads 126 disposed on the adjustable base structure. The semiconductor wafer is placed on the adjustable wafer chuck so that the contact pad is between the semiconductor wafer and the adjustable base structure.

Method 1800 includes starting a metal deposition process at act S1804. For example, the power source 114 and target 112 are operated to deposit a layer of metal, such as magnesium (Mg), aluminum (Al), strontium (Sr), iron (Fe), nickel (Ni), cobalt (Co), manganese (Mn), titanium (Ti), copper (Cu), tantalum (Ta), some other suitable metal.

Method 1800 then includes, at act S1806, performing a metal oxide deposition process. For example, oxygen is introduced inside the chamber housing 102 through shutter tube 130.

At act S1808, method 1800 includes controlling the oxidation conditions inside the chamber housing 102 to form layers or sublayers of metal oxide with precisely-controlled oxide concentrations. For example, the control module 140 may monitor conditions and/or the deposited layer. For example, the control module 140 may monitor oxygen concentrations at the wafer, and/or deposited layer thicknesses.

The control module 140 may determine that the flow rate of oxygen should be increased or decreased at the central region of the wafer and that the flow rate of oxygen should be increased or decreased at the edge region of the wafer.

In response to the determination made by the control module 140 at S1808, the control module 140 may control heights of the contact pads at act S1810. Further, the control module 140 may control the shutter tube location and flow rate of oxygen at act S1812. Thus, the control module 140 may achieve desired oxygen concentrations in the atmosphere at and around the wafer to deposit metal oxide with desired oxide concentrations.

In certain embodiments, the edge regions of contact pads are controlled, i.e., raise or lowered, to change the oxidation at the edge of the wafer, and the shutter tube is controlled to change the oxidation rate at the center of the wafer.

In certain embodiments, the oxygen flow rate is controlled from 1.7 to 1.9 standard cubic centimeters per minute (sccm).

When the desired thickness of the deposited oxide layer is obtained, which may be determined by the control module 140, the deposition process is ended at act S1814.

After forming the deposited layer, method 1800 includes checking the uniformity of the deposited film thickness at act S1816. In embodiments herein, the use of the control module 140, shutter tube 130, and adjustable wafer chuck 116 enable method 1800 to form a deposited layer with a thickness uniformity of plus or minus 10%, or plus or minus 5%. For example, a deposited layer having a thickness of 1 nanometer, may have a thickness uniformity of 1 Angstrom (0.1 nm), i.e., the difference between the deposited minimum thickness and deposited maximum thickness is no more than 0.1 nm for a 1 nm thick layer, such as no more than 0.05 nm for a 1 nm thick layer.

In an embodiment, a method includes receiving a workpiece in an apparatus for deposition, wherein the apparatus for deposition includes a chamber and electrostatic pads disposed in the chamber to accommodate the workpiece; flowing oxygen into the chamber through a shutter tube; monitoring an electrostatic accumulation over the workpiece; and adjusting the electrostatic accumulation, wherein adjusting the electrostatic accumulation includes adjusting heights of the electrostatic pads to form a deposited layer with a selected thickness uniformity.

In certain embodiments of the method, monitoring the electrostatic accumulation over the workpiece includes operating a proportional-integral-derivative control.

In certain embodiments of the method, operating a proportional-integral-derivative control further includes adjusting a flow rate of the oxygen.

In certain embodiments of the method, the flow rate of the oxygen is from 1.7 to 1.9 standard cubic centimeters per minute (sccm).

In certain embodiments of the method, adjusting the heights of the electrostatic pads includes moving at least one electrostatic pad from an initial height relative to the chamber to a second height relative to the chamber, and the initial height and the second height are up to 5 millimeters apart.

In certain embodiments of the method, the shutter tube is located at an initial location relative to the workpiece, and adjusting the electrostatic accumulation further includes moving the shutter tube to a second location relative to the workpiece to form the deposited layer with the selected thickness uniformity.

In certain embodiments of the method, the initial location and the second location are up to 25 millimeters apart.

In certain embodiments of the method, the workpiece includes a partially fabricated magnetic-tunnel junction (MTJ) film stack including a pin layer, the deposited layer is formed on the pin layer, and the deposited layer is a barrier layer comprised of aluminum oxide (AlO), magnesium oxide (MgO), strontium oxide (SrO), iron oxide (Fe2O3), nickel oxide (NiO), cobalt oxide (CoO), or manganese oxide (MnO2).

In certain embodiments of the method, the workpiece includes a partially fabricated magnetic-tunnel junction (MTJ) film stack including a free layer comprised of iron boride (FeB), molybdenum (Mo), chromium (Cr), and/or tungsten (W), wherein the deposited layer is formed on the free layer, and wherein the deposited layer is a cap layer comprised of aluminum oxide (AlO), magnesium oxide (MgO), strontium oxide (SrO), iron oxide (Fe2O3), nickel oxide (NiO), cobalt oxide (CoO), or manganese oxide (MnO2).

In another embodiment, a system for depositing a layer over a workpiece is provided. The system includes a chamber housing; an adjustable wafer chuck configured to receive the workpiece, wherein the adjustable wafer chuck includes electrostatic pads; a shutter tube for flowing oxygen inside the chamber housing; and a controller for monitoring an electrostatic accumulation over the workpiece, wherein the controller is configured to adjust heights of the electrostatic pads to form a deposited layer with a selected thickness uniformity.

In certain embodiments of the system, the controller is configured to adjust a flow rate of the oxygen from the shutter tube.

In certain embodiments of the method, the controller is configured to move the shutter tube laterally to adjust formation of the deposited layer.

In certain embodiments of the method, the shutter tube is adjustable laterally by up to 25 millimeters.

In certain embodiments of the method, the controller is a proportional-integral-derivative controller.

In certain embodiments of the method, the heights of the electrostatic pads are adjustable by up to 5 millimeters.

In another embodiment, a semiconductor structure includes a bottom portion of the semiconductor structure; a metal oxide layer located on the bottom portion of the semiconductor structure, wherein the metal oxide layer has a minimum thickness and a maximum thickness, wherein a difference between the minimum thickness and the maximum thickness is less than ten percent of the maximum thickness, wherein the metal oxide layer is formed by physical vapor deposition process in which relative heights of portions of the bottom portion of the semiconductor structure are dynamically adjusted.

In certain embodiments of the semiconductor structure, the bottom portion of the semiconductor structure is a bottom portion of a magnetic-tunnel junction (MTJ) film stack.

In certain embodiments of the semiconductor structure, the bottom portion of the semiconductor structure is a bottom portion of a magnetic-tunnel junction (MTJ) film stack, and the metal oxide layer is a barrier layer located on a pin layer.

In certain embodiments of the semiconductor structure, the bottom portion of the semiconductor structure is a bottom portion of a magnetic-tunnel junction (MTJ) film stack, and the metal oxide layer is a cap layer located on a free layer.

In certain embodiments of the semiconductor structure, the metal oxide layer is comprised of aluminum oxide (AlO), magnesium oxide (MgO), strontium oxide (SrO), iron oxide (Fe2O3), nickel oxide (NiO), cobalt oxide (CoO), or manganese oxide (MnO2).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
receiving a workpiece in an apparatus for deposition, wherein the apparatus for deposition comprises a chamber and electrostatic pads disposed in the chamber to accommodate the workpiece;
flowing oxygen into the chamber through a shutter tube;
monitoring an electrostatic accumulation over the workpiece; and
adjusting the electrostatic accumulation, wherein adjusting the electrostatic accumulation comprises adjusting heights of the electrostatic pads to form a deposited layer with a selected thickness uniformity.

2. The method of claim 1, wherein monitoring the electrostatic accumulation over the workpiece comprises operating a proportional-integral-derivative control.

3. The method of claim 2, wherein operating a proportional-integral-derivative control further comprises adjusting a flow rate of the oxygen.

4. The method of claim 3, wherein the flow rate of the oxygen is from 1.7 to 1.9 standard cubic centimeters per minute (sccm).

5. The method of claim 1, wherein adjusting the heights of the electrostatic pads comprises moving at least one electrostatic pad from an initial height relative to the chamber to a second height relative to the chamber, and wherein the initial height and the second height are up to 5 millimeters apart.

6. The method of claim 1, wherein the shutter tube is located at an initial location relative to the workpiece, and wherein adjusting the electrostatic accumulation further comprises moving the shutter tube to a second location relative to the workpiece to form the deposited layer with the selected thickness uniformity.

7. The method of claim 6, wherein the initial location and the second location are up to 25 millimeters apart.

8. The method of claim 1, wherein the workpiece comprises a partially fabricated magnetic-tunnel junction (MTJ) film stack including a pin layer, wherein the deposited layer is formed on the pin layer, and wherein the deposited layer is a barrier layer comprised of aluminum oxide (AlO), magnesium oxide (MgO), strontium oxide (SrO), iron oxide (Fe2O3), nickel oxide (NiO), cobalt oxide (CoO), or manganese oxide (MnO2).

9. The method of claim 1, wherein the workpiece comprises a partially fabricated magnetic-tunnel junction (MTJ) film stack including a free layer comprised of iron boride (FeB), molybdenum (Mo), chromium (Cr), and/or tungsten (W), wherein the deposited layer is formed on the free layer, and wherein the deposited layer is a cap layer comprised of aluminum oxide (AlO), magnesium oxide (MgO), strontium oxide (SrO), iron oxide (Fe2O3), nickel oxide (NiO), cobalt oxide (CoO), or manganese oxide (MnO2).

10. A system for depositing a layer over a workpiece, the system comprising:
a chamber housing;
an adjustable wafer chuck configured to receive the workpiece, wherein the adjustable wafer chuck includes electrostatic pads;
a shutter tube for flowing oxygen inside the chamber housing;
a controller for monitoring an electrostatic accumulation over the workpiece, wherein the controller is configured to adjust heights of the electrostatic pads to form a deposited layer with a selected thickness uniformity.

11. The system of claim 10, wherein the controller is configured to adjust a flow rate of the oxygen from the shutter tube.

12. The system of claim 10, wherein the controller is configured to move the shutter tube laterally to adjust formation of the deposited layer.

13. The system of claim 12, wherein the shutter tube is adjustable laterally by up to 25 millimeters.

14. The system of claim 10, wherein the controller is a proportional-integral-derivative controller.

15. The system of claim 10, wherein the heights of the electrostatic pads are adjustable by up to 5 millimeters.

16. A semiconductor structure comprising:
a bottom portion of the semiconductor structure;
a metal oxide layer located on the bottom portion of the semiconductor structure, wherein the metal oxide layer has a minimum thickness and a maximum thickness, wherein a difference between the minimum thickness and the maximum thickness is less than ten percent of the maximum thickness, wherein the metal oxide layer is formed by physical vapor deposition process in which relative heights of portions of the bottom portion of the semiconductor structure are dynamically adjusted.

17. The semiconductor structure of claim 16, wherein the bottom portion of the semiconductor structure is a bottom portion of a magnetic-tunnel junction (MTJ) film stack.

18. The semiconductor structure of claim 16, wherein the bottom portion of the semiconductor structure is a bottom portion of a magnetic-tunnel junction (MTJ) film stack, and wherein the metal oxide layer is a barrier layer located on a pin layer.

19. The semiconductor structure of claim 16, wherein the bottom portion of the semiconductor structure is a bottom portion of a magnetic-tunnel junction (MTJ) film stack, and wherein the metal oxide layer is a cap layer located on a free layer.

20. The semiconductor structure of claim 16, wherein the metal oxide layer is comprised of aluminum oxide (AlO), magnesium oxide (MgO), strontium oxide (SrO), iron oxide (Fe2O3), nickel oxide (NiO), cobalt oxide (CoO), or manganese oxide (MnO2).
